(19) United States
(12) Patent Application Publication
(10) Pub. No.: US 2016/0268294 A1
(43) Pub. Date: Sep. 15, 2016

(54) SEMICONDUCTOR DEVICE AND METHOD FOR FORMING PATTERN IN CONDUCTIVE LAYER

(71) Applicant: Kabushiki Kaisha Toshiba, Minato-ku (JP)

(72) Inventors: Junichi HASHIMOTO, Yokkaichi (JP); Toru MATSUDA, Yokkaichi (JP); Katsuhiro ISHIDA, Yokkaichi (JP); Hidetaka NAMBU, Yokkaichi (JP)

(73) Assignee: Kabushiki Kaisha Toshiba, Minato-ku (JP)

(21) Appl. No.: 14/827,507

(22) Filed: Aug. 17, 2015

Related U.S. Application Data
(60) Provisional application No. 62/133,001, filed on Mar. 13, 2015.

(51) Int. Cl. H01L 27/115; H01L 21/3213; H01L 21/768

(52) U.S. Cl. CPC H01L 27/11582; H01L 21/76892; H01L 27/11556; H01L 21/32139

(57) ABSTRACT

A method for forming a pattern in a conductive layer includes forming the conductive layer on an insulating layer, forming an etching mask on the conductive layer, and selectively etching the conductive layer to reach the insulating layer by using the etching mask. The etching mask includes a first portion masking a first area of the conductive layer, a second portion masking a second area that surrounds the first area via at least one opening that defines a boundary between the first portion and the second portion. The etching mask also includes a first communication portion connecting the first portion and the second portion. The at least one opening includes overlapping portions, and the first communication portion is provided between the overlapping portions.

### CROSS-REFERENCE TO RELATED APPLICATIONS

This application is based upon and claims the benefit of priority from U.S. Provisional Patent Application 62/133,001 filed on Mar. 13, 2015; the entire contents of which are incorporated herein by reference.

### FIELD

Embodiments are related generally to a semiconductor device and a method for forming a pattern in a conductive layer.

### BACKGROUND

A semiconductor memory device comprising three dimensionally arranged memory cells is under development in order to increase an integration degree thereof. For example, there is a NAND-type semiconductor memory device including semiconductor layers that extend in a direction perpendicular to an underlying layer, memory cells disposed along the semiconductor layers, and electrodes stacked on the underlying layer. The semiconductor layers each extend through the stacked electrodes, and the memory cells are provided at a crossed portion of a semiconductor layer and an electrode. Each electrode becomes thinner as the memory cells are integrated at a higher degree. When the electrodes are made, for example, of conductive polysilicon, the electrical resistance thereof becomes larger and provides a semiconductor memory device with the inferior performance. Thus, the electrodes are preferably formed from a metal instead of the polysilicon. Replacing the polysilicon with the metal, however, increases complexity in the manufacturing process, and requires a technology for improving accuracy thereof.

### BRIEF DESCRIPTION OF THE DRAWINGS

FIG. 1 is a schematic cross-sectional view showing a semiconductor memory device according to an embodiment;

FIGS. 2A and 2B are schematic plan views showing the semiconductor memory device according to the embodiment;

FIGS. 3 to 9 are schematic cross-sectional views showing a manufacturing process of the semiconductor memory device according to the embodiment;

FIG. 10A is a schematic plan view showing a process for forming a mask pattern according to the embodiment, and FIG. 10B is a scanning electron microscope image thereof;

FIG. 11A is a schematic plan view showing a process for forming a mask pattern according to a comparative example, and

FIG. 11B is a scanning electron microscope image thereof;

FIGS. 12A and 12B are schematic plan views showing mask patterns according to a variation of the embodiment;

FIGS. 13A to 13D are schematic plan views showing mask patterns according to another variation of the embodiment; and

FIG. 14 is a schematic plan view showing a mask pattern according to other variation of the embodiment.

### DETAILED DESCRIPTION

A method for forming a pattern in a conductive layer includes forming the conductive layer on an insulating layer, forming an etching mask on the conductive layer, and selectively etching the conductive layer to reach the insulating layer by using the etching mask. The etching mask includes a first portion masking a first area of the conductive layer, a second portion masking a second area that surrounds the first area via at least one opening that defines a boundary between the first portion and the second portion. The etching mask also includes a first communication portion connecting the first portion and the second portion. The at least one opening includes overlapping portions, and the first communication portion is provided between the overlapping portions.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

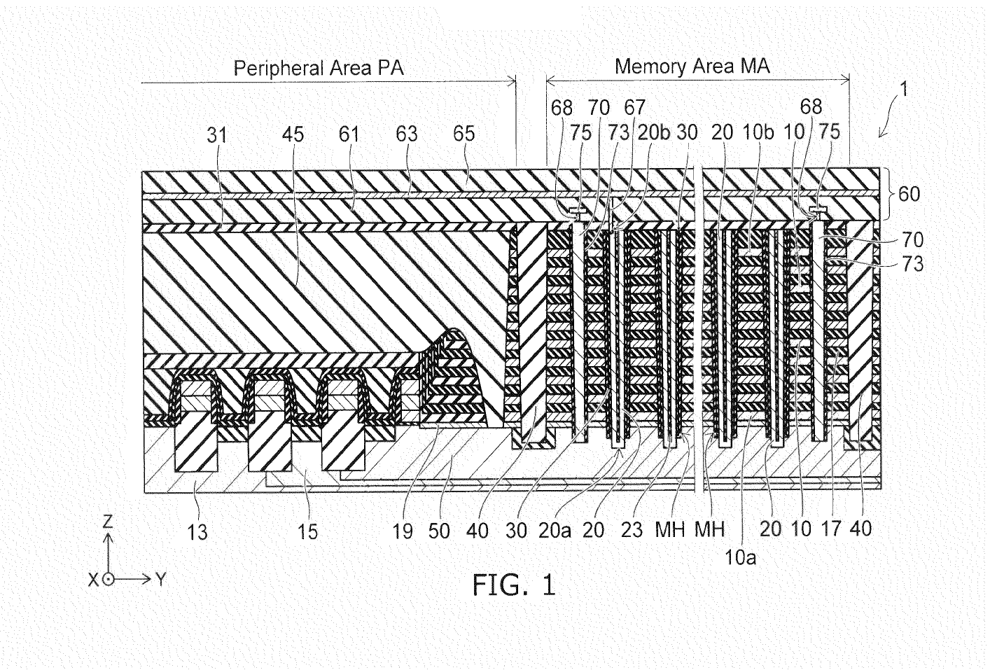

FIG. 1 is a schematic cross-sectional view showing a semiconductor memory device 1 according to an embodiment. The semiconductor memory device 1 is, for example, a NAND-type flash memory and has a first area (hereinafter referred to as a memory area MA) and a second area (hereinafter referred to as a peripheral area PA) around the first area.

The memory area MA includes a plurality of memory cells. Specifically, the memory area includes electrodes 10, which are arranged in a first direction (hereinafter referred to as the Z direction), and semiconductor layers 20, which extend in the Z direction through the electrodes 10. A memory layer 30 is provided between each electrode 10 and a semiconductor layer 20.

The memory layer 30 has, for example, a multilayer structure including a tunnel insulating layer, a charge storage layer, and a block insulating layer, which are sequentially stacked on an outer surface of a semiconductor layer 20. A memory cell includes a part of the memory layers 30 that is provided between the semiconductor layer 20 and an electrode 10. A plurality of memory cells shares the semiconductor layer 20. That is, the memory cells are arranged in the Z-direction along the semiconductor layers 20.

The peripheral area PA includes a peripheral circuit (not shown). The peripheral circuit drives the memory cells via the electrodes 10 and the semiconductor layers 20. A boundary wall 40 is provided between the memory area MA and the peripheral area PA. The boundary wall 40 is, for example, a silicon oxide layer. The boundary wall 40 extends in the Z direction and separates the memory area MA and the peripheral area PA. As will be described later, the boundary wall 40 prevents an etchant of sacrifice layers 103 from penetrating into the peripheral area PA in the process of replacing sacrifice layers 103 with the electrodes 10.

The memory area MA includes a plurality of semiconductor layers 20, as shown in FIG. 1. The semiconductor layers 20 are provided, for example, in a plurality of memory holes MH arranged in the X-direction and the Y-direction. Each memory hole MH extends through the electrodes 10 and insulating layers 17. The electrodes 10 are stacked in the Z direction, and the insulating layers 17 are provided between the electrodes 10. Each memory hole MH includes a memory layer 30 and a semiconductor layer 20. The memory layer 30 is provided on an inner surface of the memory hole MH, and the semiconductor layer 20 is provided on the memory layer 30. Each memory hole MH may include a core 23, which is, for example, provided on the semiconductor layer 20 and fills the interior space of the memory hole MH.

The memory area MA is formed, for example, on a source layer 50 (conductive layer). The source layer 50 is, for example, a P-type well provided on a semiconductor substrate 13 and has conductivity. Alternatively, the source layer 50 may be an N-type well 15 provided in the semiconductor substrate 13.

An interconnect layer 60 is provided on the memory area MA. The interconnect layer 60 extends over the memory area MA and the peripheral area PA. The interconnect layer 60 includes, for example, an interlayer insulating layer 61, bit lines 63, and an interlayer insulating layer 65. The interconnect layer 60 further includes source lines 75.

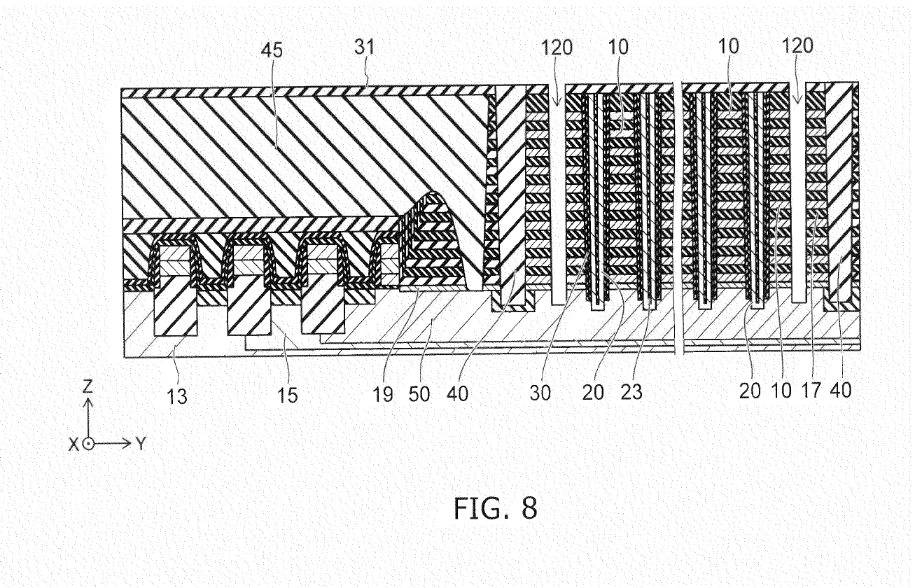

The source lines 75 are electrically connected to the source layer 50, for example, via conductive bodies 70 and contact plugs 68, as shown in FIG. 1. The conductive bodies 70 are provided in slits 120 via insulating layers 73, which are formed between adjacent ones of the electrodes 10 (see FIG. 8). The conductive bodies also provided between the boundary wall 40 and an electrode 10 adjacent thereto.

The semiconductor layer 20 is electrically connected to the source layer 50 at one end 20a thereof. The semiconductor layer 20 is electrically connected to a bit line 63 via a contact plug 67 at the other end 20b thereof.

The electrodes 10 include an electrode 10a located at a lowest position and an electrode 10b located at a highest position. The electrode 10a acts as a selection gate that turns electrical conduction on or off between the semiconductor layers 20 and the source layer 50. The electrode 10a acts as a selection gate that turns electrical conduction on or off between the semiconductor layers 20 and the bit lines 63.

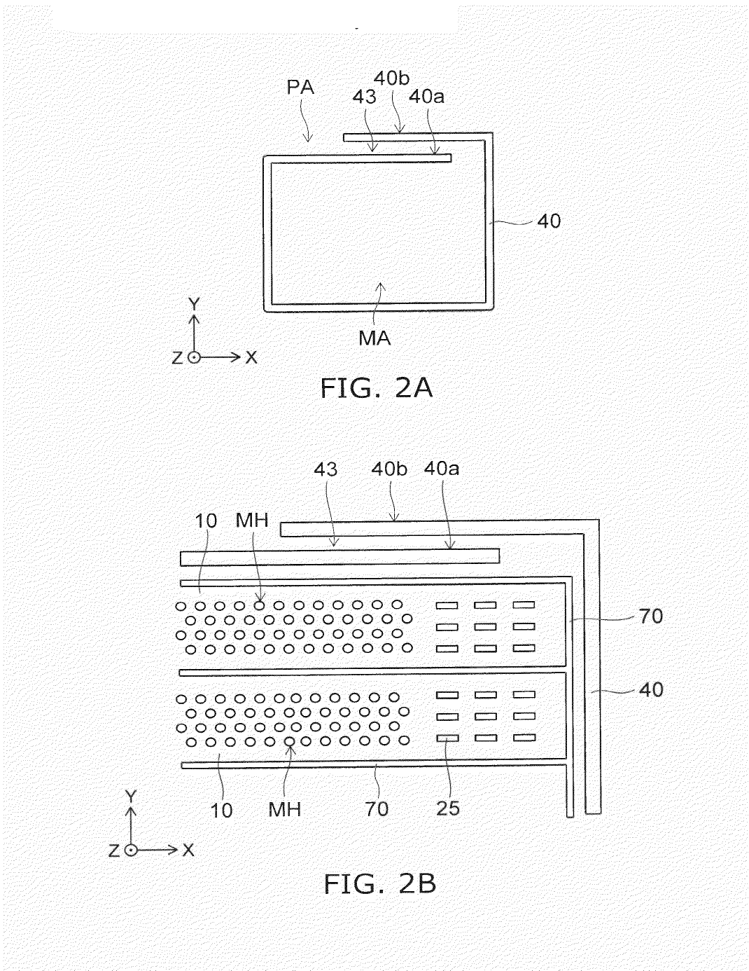

FIGS. 2A and 2B are schematic plan views showing the semiconductor memory device 1 according to the embodiment. FIG. 2A is a plan view schematically showing the structure of the boundary wall 40. FIG. 2B is a plan view schematically showing a part of the memory area MA and a part of the boundary wall 40.

The boundary wall 40 surrounds the memory area MA, as shown in FIG. 2A. The boundary wall 40 has a communication portion 43 at least at a part of the boundary wall 40, in which the peripheral area PA is in communication with the memory area MA. The boundary wall 40 has, for example, a first portion 40a and a second portion 40b. The second portion 40b overlaps with the first portion 40a in the direction from the memory area MA toward the peripheral area PA (a Y-direction, for example). The communication portion 43 is provided between the first portion 40a and the second portion 40b.

The memory area MA includes the electrodes 10 arranged in the Y direction, as shown in FIG. 2B. A plurality of memory holes MH are provided in each electrode 10. Each electrode 10 is surrounded by a conductive body 70. A plurality of support pillars 25 are provided in each electrode 10. As will be described later, the support pillars 25 support the plurality of insulating layers 17, which are disposed in the Z direction in the process of forming the electrodes 10.

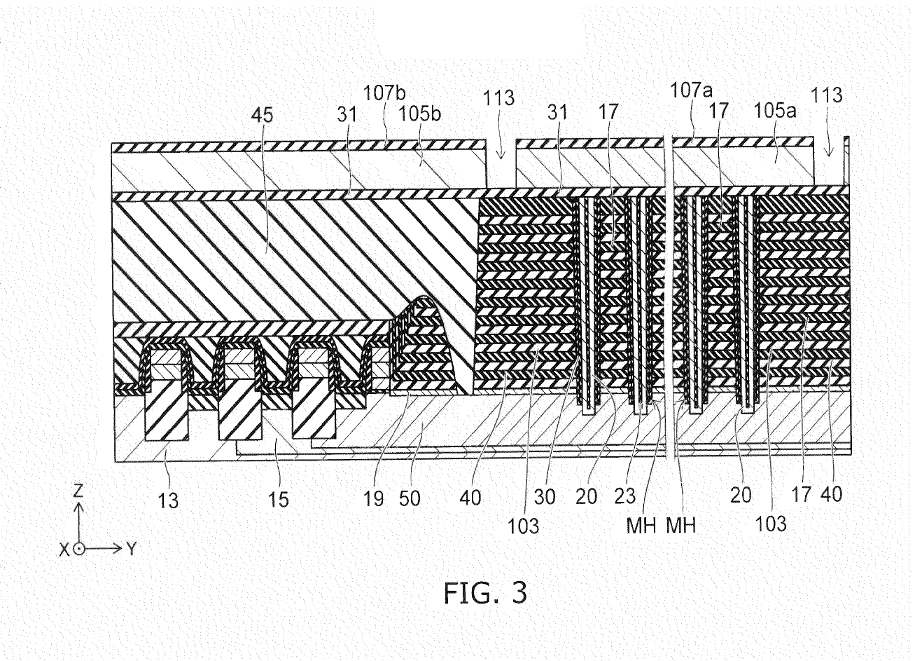

A method of manufacturing the semiconductor memory device 1 according to the embodiment will then be described with reference to FIGS. 3 to 9. FIGS. 3 to 9 are schematic cross-sectional views sequentially showing the processes of manufacturing the semiconductor memory device 1.

FIG. 3 shows a conductive layer 105 formed on the memory area MA and the peripheral area PA. A plurality of memory holes MH are formed in the memory area MA, and the semiconductor layer 20 and the memory layer 30 are formed in each memory hole MH. An insulating layer 45 is formed on the peripheral area PA. The insulating layer 45 covers a peripheral circuit (not shown) formed on the semiconductor substrate 13. The insulating layer 45 fills the step between the memory area MA and the peripheral area PA so that a surface of the peripheral area PA is in plane with a surface of the memory area.

The memory holes MH are formed to pass through the insulating layers 17 and the sacrifice layers 103 on the source layer 50, for example, by the use of RIE (Reactive Ion Etching). The insulating layers 17 and the sacrifice layers 103 are alternately stacked in the Z direction. Each of the insulating layers 17 is, for example, a silicon oxide layer. Each of the sacrifice layers 103 is, for example, a silicon nitride layer or a polysilicon layer. The sacrifice layers 103 are made of a material that can be removed selectively from the insulating layers 17.

Each of the memory layers 30 has, for example, a multilayer structure including a silicon oxide layer (tunnel insulating layer), a silicon nitride layer (charge storage layer), and a silicon oxide layer (block insulating layer). For example, the silicon oxide layer that acts as the block insulating layer is formed on the inner surface of each memory hole MH. The silicon nitride layer is formed on the silicon oxide layer, and the silicon oxide layer is further formed on the silicon nitride layer.

The conductive layer 105 is provided on an insulating layer 31, which covers the memory area MA and the peripheral area PA. The conductive layer 105 is selectively etched by using a mask 107a, which covers the memory area MA, and a mask 107b which covers the peripheral area PA. The conductive layer 105 is divided by a groove 113 into a conductive layer 105a, which covers the memory area MA, and a conductive layer 105b, which covers the peripheral area PA.

The conductive layer 105 is, for example, a carbon layer, which is formed by the use of CVD (chemical vapor deposition). To enlarge the ratio of the etching rates of the insulating layers 17, 31 and the sacrifice layers 103 to the etching rate of the conductive layer 105, the conductive layer 105 preferably has a higher carbon concentration. Thus, the conductive layer 105 is preferably formed at a temperature higher than or equal to 650° C.

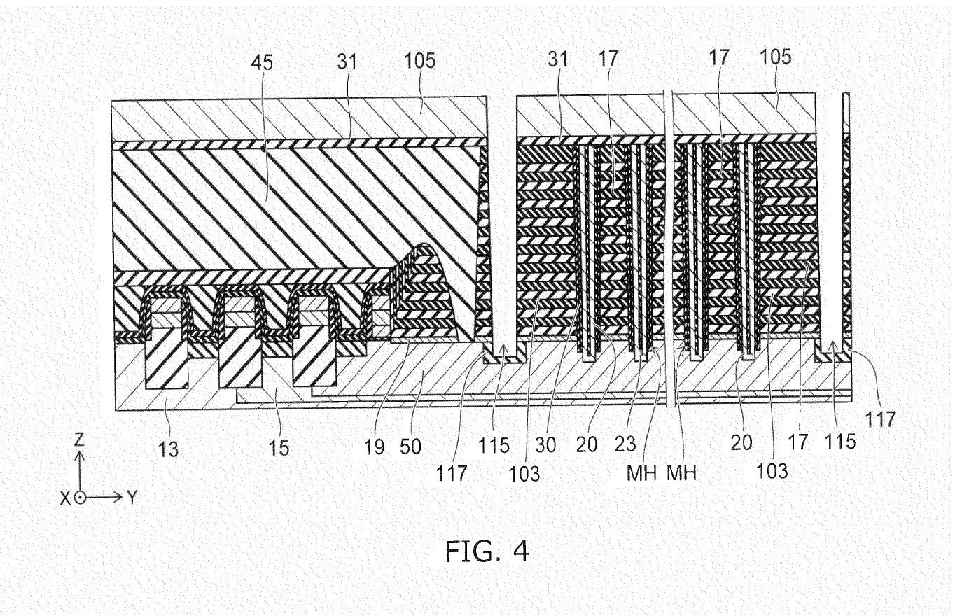

FIG. 4 is a cross-sectional view showing a groove 115 formed at the boundary between the memory area MA and the peripheral area PA. The groove 115 is formed by selectively removing the insulating layers 17 and 31 and the sacrifice layers 103 by the use of the conductive layer 105 as an etching mask. Further, holes for forming the support pillars 25 may be formed in the memory area MA simultaneously with the groove 115. The groove 115 is formed to have a depth reaching the source layer 50 from the upper surface of the insulating layer 31. An insulating layer 117 is formed on a surface of the source layer 50, which is exposed at a bottom of the groove 115. The insulating layer 117 is formed, for example, by oxidizing the source layer 50 in plasma.

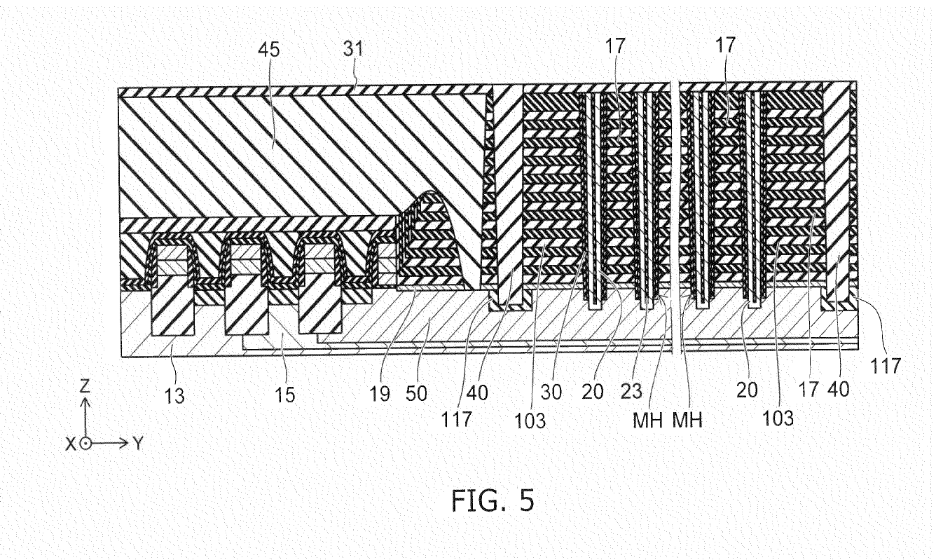

FIG. 5 is a cross-sectional view showing the boundary wall 40 formed in the groove 115. The boundary wall 40 is, for example, a silicon oxide layer buried in the groove 115. Silicon oxide layers that form the support pillars 25 (see FIG. 2B) may be formed in the memory area MA simultaneously with the silicon oxide layer that forms the boundary wall 40.

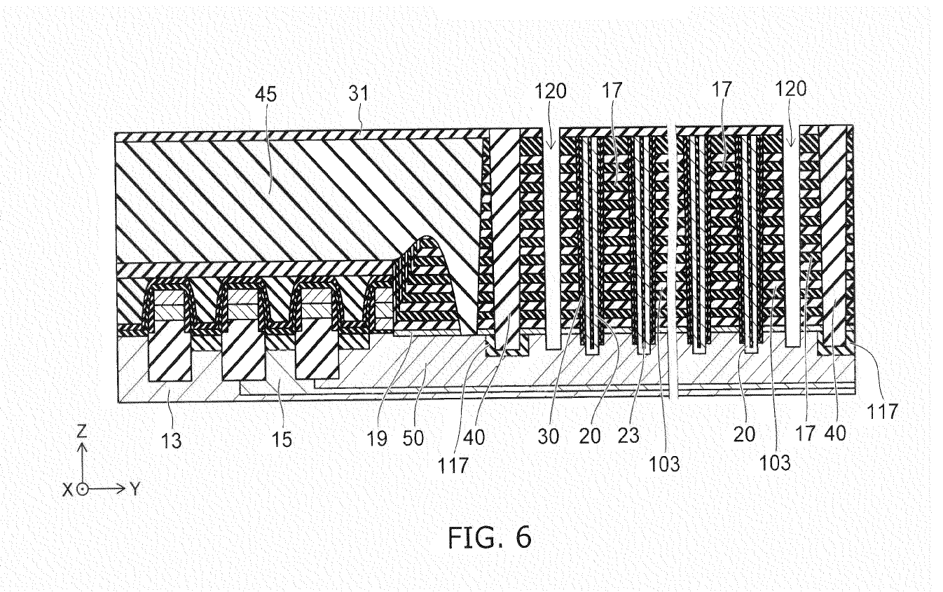

FIG. 6 is a cross-sectional view showing the slits 120 formed in the memory area MA. The slits 120 are formed by selectively removing the insulating layers 31 and 17 and the sacrifice layers 103. The slits 120 are formed to have a depth extending through an insulating layer 19 and reaching the source layer 50 from the upper surface of the insulating layer 31.

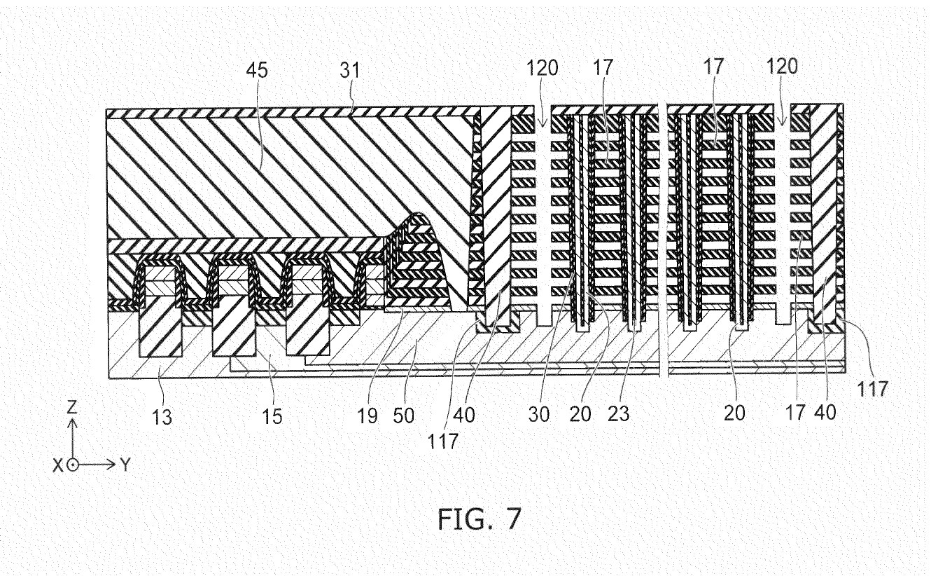

FIG. 7 is a schematic view showing a cross section after the sacrifice layers 103 is selectively removed. The sacrifice layers 103 are selectively removed, for example, using an etchant that does not etch the insulating layers 31, 17, or 19. For example, when each sacrifice layer 103 is a silicon nitride layer, a phosphoric acid solution may be used as the etchant. The etchant is supplied through the slits 120 and etches the sacrifice layers 103. The boundary wall 40 may prevent the etchant from leaking out of the memory area MA.

The boundary wall 40 according to the embodiment has the communication portion 43, as shown in FIG. 2B. Thus, the etchant may penetrate undesirably into the peripheral area PA through the communication portion 43, when it takes a long time to etch the sacrifice layers 103. To avoid this, the etching period for removing the sacrifice layers 103 may be set to be longer than a period that is necessary for completely removing the sacrifice layers 103 in the memory area MA, and shorter than a period that is necessary for the etchant to penetrate into the peripheral area PA through the communication portion 43.

Spaces left after removing the sacrifice layers 103 are maintained by the semiconductor layers 20 and the memory layers 30, which support the insulating layers 17 and 31, as shown in FIG. 7. In a portion where no semiconductor layers 20 or memory layers 30 are provided, the insulating layers 17 and 31 are supported by the support pillars 25 in a portion without the semiconductor layer 20 and the memory layer 30.

FIG. 8 is a cross-sectional view showing the electrodes 10 formed in the spaces left after removing the sacrifice layers 103. A metal layer made, for example, of tungsten (W) is deposited by using a CVD method in each space left after removing the sacrifice layers 103. The raw materials are supplied through the slits 120 for depositing the metal layer in the spaces. A metal layer is also formed on the inner surfaces of the slits 120, and then, it is removed by dry etching for making the electrodes 10.

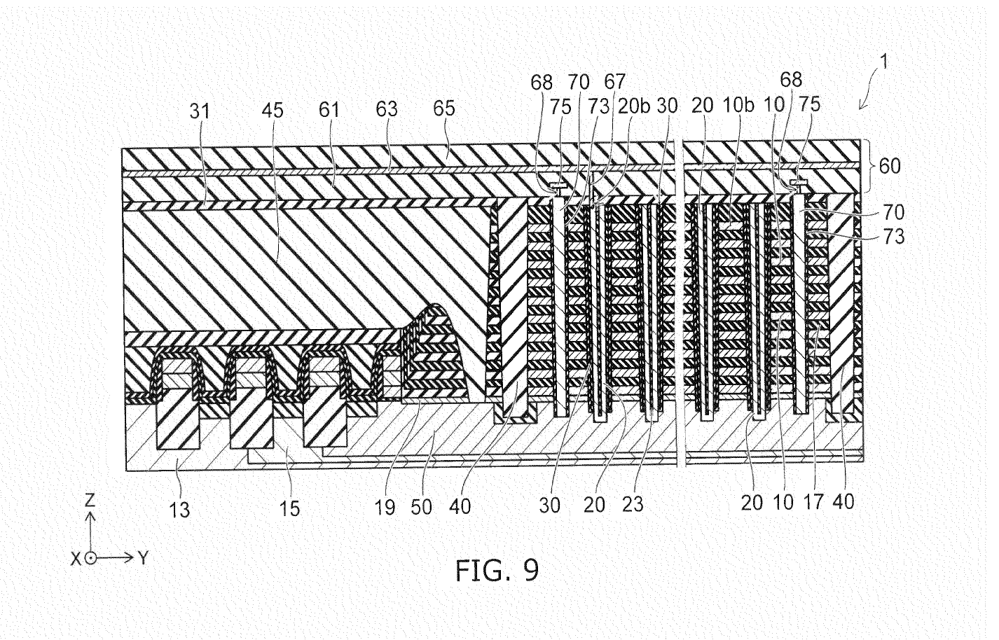

FIG. 9 is a cross-sectional view showing the insulating layers 73 and the conductive bodies 70, which are formed in the slits 120, and the interconnect layer 60. In the slits 120, for example, silicon oxide layers are formed as the insulating layers 73, and tungsten layers are buried as the conductive bodies 70. The interconnect layer 60 is formed on the memory area MA and the peripheral area PA, and the semiconductor layers 20 is electrically connected to the bit lines 63. The source layer 50 is electrically connected to the source line 75 via the conductive bodies 70.

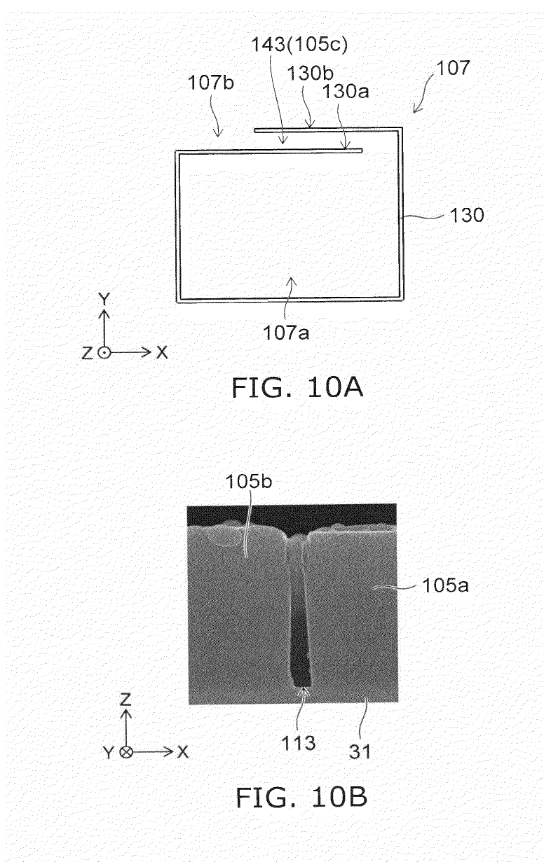

FIGS. 10A and 10B are a schematic plan view and a scanning electron microscope image (SEM image) showing a process for forming the mask pattern according to the embodiment. FIG. 10A is a plan view showing a mask 107 used for etching the conductive layer 105. FIG. 10B is an SEM image showing a cross section of the groove 113 formed in the conductive layer 105.

The mask 107 includes the masking portion 107a, the masking portion 107b, and an opening 130, as shown in FIG. 10A. The masking portion 107a covers the memory area MA, and the masking portion 107b covers the peripheral area PA. The opening 130 defines the boundary between the mask 107a and the mask 107b. The mask 107 further includes a communication portion 143 that connects the masking portion 107a and the masking portion 107b. The opening 130 has a first end portion 130a and a second end portion 130b. The opening 130 is formed such that the first end portion 130a overlaps the second end portion 130b in the direction from the masking portion 107a toward the masking portion 107b (the Y direction, for example).

The groove 113 may be selectively formed by using the mask 107. The groove 113 is provided to reach the insulating layer 31 from the upper surface of the conductive layer 105, as shown in FIG. 10B. The conductive layer 105 is separated by the groove 113 into the conductive layers 105a and 105b. The conductive layer 105a covers the memory area MA, and the conductive layer 105b covers the peripheral area PA. A communication portion 105c, which electrically connects the conductive layer 105a and the conductive layer 105b, is formed under the communication portion 13.

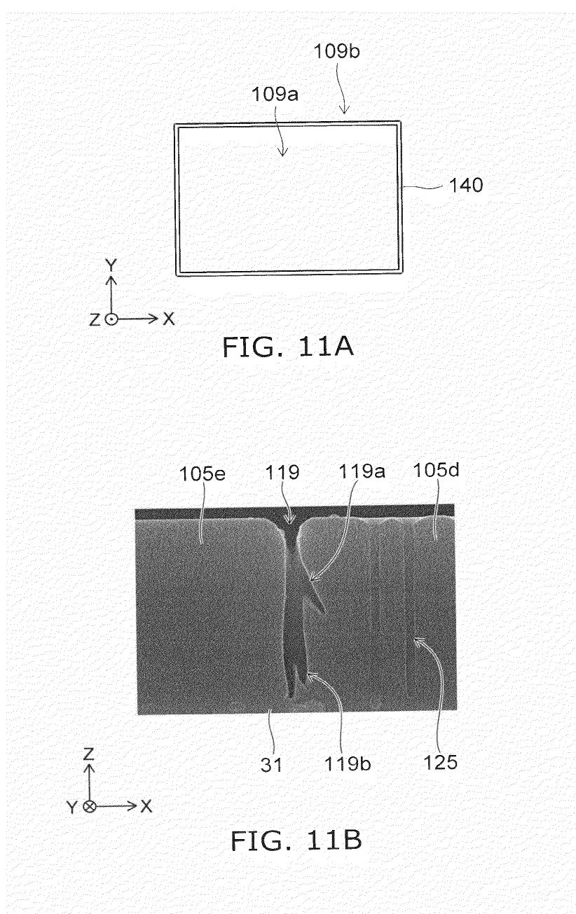

FIGS. 11A and 11B are a schematic plan view and a scanning electron microscope image showing a process for forming a mask pattern according to a comparative example. FIG. 11A is a plan view showing a mask 109 according to the comparative example. FIG. 11B is a cross-sectional SEM image showing a cross section of a groove 119 formed in the conductive layer 105.

The mask 109 includes a masking portion 109a, a masking portion 109b, and an opening 140, as shown in FIG. 11A. The masking portion 109a covers the memory area MA, and the masking portion 109b covers the peripheral area PA. The opening 140 defines the boundary between the masking portion 109a and the masking portion 109b. In this example, the masking portion 109a and the masking portion 109b are separated from each other by the opening 140, and no communication portion is provided.

The mask 109 is used to form the groove 119 in the conductive layer 105, as shown in FIG. 11B. The conductive layer 105 is divided into a conductive layer 105d and a conductive layer 105e. The conductive layer 105d covers the memory area MA, and the conductive layer 105e covers the peripheral area PA. The groove 119 has branches 119a and 119b in the cross-section thereof, for example. The branches may be generated by ions having curved trajectory in a dry-etching process for forming the groove 119.

For example, in the dry-etching process, charges of the ions are transferred to the conductive layer 105. Before the groove 119 reaches the insulating layer 31, the conductive layer 105d and the conductive layer 105e are electrically connected to each other, and hence, have the same potential. Once the groove 119 reaches the insulating layer 31, however, the conductive layer 105d and the conductive layer 105e are electrically insulated from each other. When the etching continues after the groove 119 reaches the insulating layer 31, the conductive layer 105d is charged up with charges transferred from the ions. Then, a potential difference is formed between the conductive layer 105d and the conductive layer 105e, and makes the ion trajectory unstable. As a result, the branches 119a and 119b may be formed in the conductive layer 105d as shown in FIG. 11B. For example, the conductive layer 105d also has openings 125 for forming the support pillars 25. Since the openings 125 are formed in a portion without a potential difference, the support pillars 25 is formed with a straight shape having no branch as shown in FIG. 11B.

In the method for forming the mask pattern according to the embodiment, the conductive layer 105a and the conductive layer 105b are formed with an electrical connection via the communication portion 105c. Thus, the conductive layers 105a and 105b are formed under the same potential. The groove 113 is formed with a cross-sectional shape extending straight from the upper surface of the conductive layer 105 to the insulating layer 31 as shown in FIG. 10B.

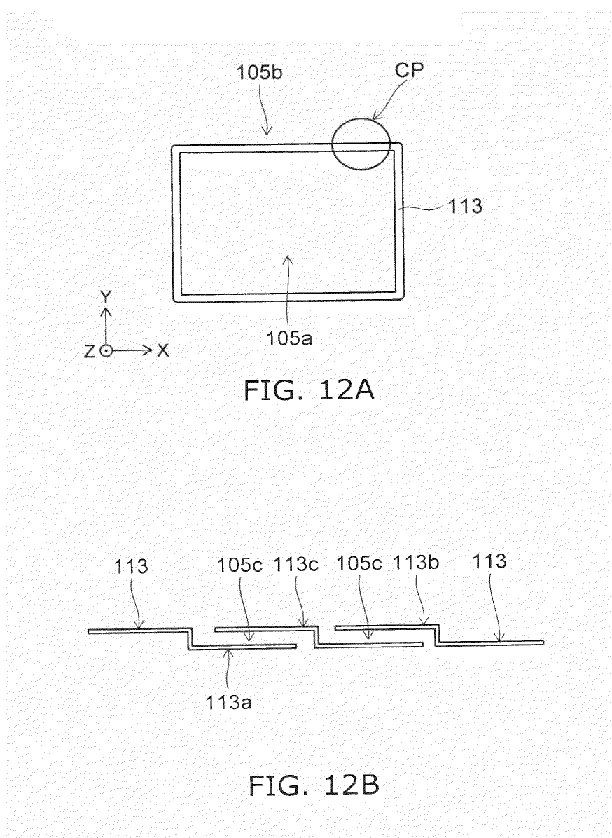

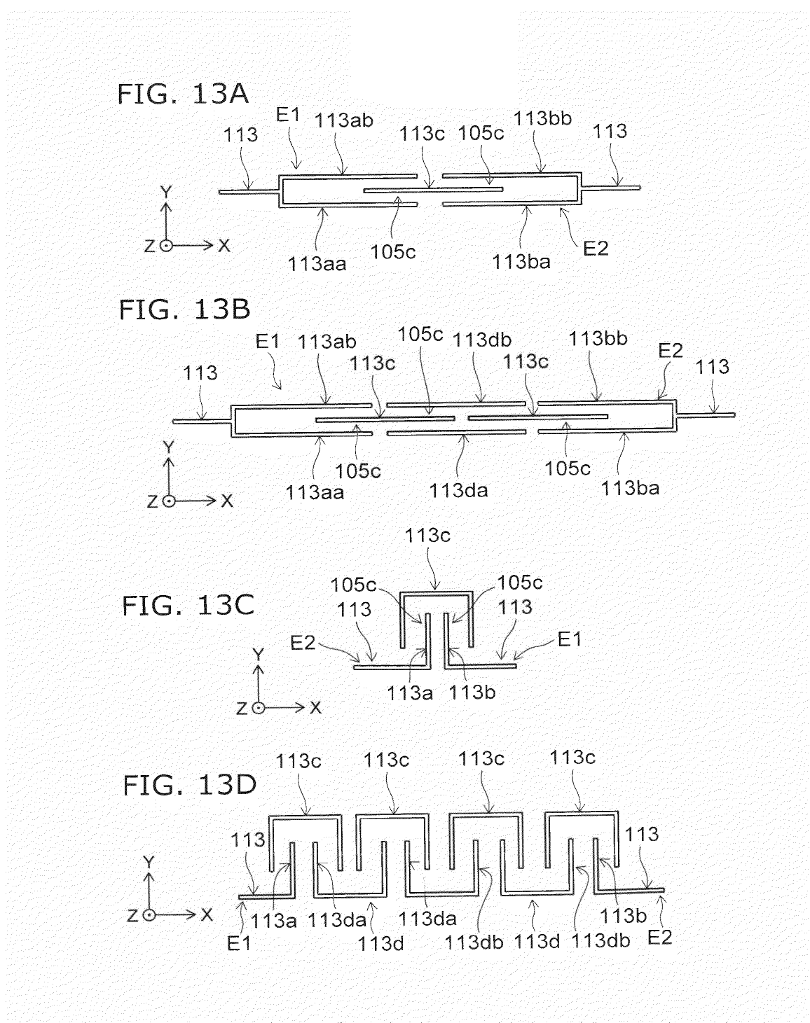

FIGS. 12A to 13D are schematic plan views showing mask patterns according to variations of the embodiment. FIG. 12A is a plan view showing a shape of the groove 113 formed in the conductive layer 105. FIGS. 12B to 13D are enlarged views showing an area CP shown in FIG. 12A.

Each of the conductive masks according to the variations includes the conductive layer 105a, the conductive layer 105b and the groove 113. The conductive layer 105b surrounds the conductive layer 105a as shown in FIG. 12A. The groove 113 defines the boundary between the conductive layer 105a and the conductive layer 105b.

The groove 113 shown in FIG. 12B has two end portions in the area CR The groove 113 has a first portion 113a and a second portion 113b at the two end portions respectively. The groove 113 further has a third portion 113c, which is separate from the first portion 113a and the second portion 113b. The third portion 113c overlaps with the first portion 113a and the second portion 113b, for example, in the Y direction. One part of the third portion 113c locates on the conductive layer 105b side of the first portion 113a, and the other part of the third portion locates on the conductive layer 105a side of the second portion 113b. The communication portions 105c are provided respectively between the first portion 113a and the third portion 113c and between the second portion 113b and the third portion 113c.

The groove 113 shown in FIG. 13A has two end portions E₁ and E₂ in the area CP. The end portion E₁ bifurcates into first portions 113aa and 113ab, and the end portion E₂ bifurcates into second portions 113ba and 113bb. The groove 113 has a third portion 113c, which is separated from the two end portions E₁ and E₂. The third portion 113c extends between the first portions 113aa and 113ab at the end portion E₁. The third portion 113c overlaps with the first portions 113aa and 113ab, for example, in the Y direction. The third portion 113c also extends between the second portions 113ba and 113bb at the end portion E2. The third portion 113c overlaps with the second portions 113ba and 113bb, for example, in the Y direction. The communication portions 105c are provided respectively between the first portion 113aa and the third portion 113c and between the first portion 113ab and the third portion 113c. The communication portions 105c are also provided respectively between the second portion 113ba and the third portion 113c and between the second portion 113bb and the third portion 11c.

The groove 113 shown in FIG. 13B may have two third portions 113c and fourth portions 113da and 113db between the two end portions E₁ and E₂. The two third portions 113c and fourth portions 113da and 113db are separated from the two end portions E₁ and E₂. One of the two third portions 113c extends between the first portion 113aa and the first portion 113ab at the end portion E. The one of the two third portions 113c also extends between the fourth portion 113da and the fourth portion 113db. The fourth portion 113da and the fourth portion 113db are separated from both end portions E₁ and E₂. The other one of the two third portions 113c extends between the second portion 113ba and the second portion 113bb at the end portion E₂. The other one of the two third portions 113c also extends between the fourth portion 113da and the fourth portion 113db. The one of the two third portions 113c overlaps with the first portions 113aa and 113ab, and the other of the two third portions 113c overlaps with the second portions 113ba and 113bb, for example, in the Y direction. The two third portions 113c further overlap with the fourth portions 113da and 113db, for example, in the Y direction.

The groove 113 shown in FIG. 13C has two end portions E₁ and E₂ in the area CP. The groove 113 has a first portion 113a and a second portion 113b respectively at the two end portions. The first portion 113a and the second portion 113b extend, for example, in a direction from the conductive layer 105a toward the conductive layer 105b (the Y direction, for example). The groove 113 further has, which is separated from the first portion 113a and the second portion 113b. The third portion 113c overlaps with the first portion 113a and the second portion 113b, for example, in the X and Y directions. The third portion 113c is provided around the first portion 113a and the second portion 113b. The communication portions 105c are provided respectively between the first portion 113a and the third portion 113c and between the second portion 113b and the third portion 113c.

The groove 113 shown in FIG. 13D may further have at least two third portions 113c and at least one fourth portion 113d between the two end portions E₁ and E₂. The at least two third portions 113c and the at least one fourth portion are separated from each other. Both ends of the fourth portion 113d extend in the Y direction. For example, one third portion 113c is provided around the first portion 113a and an end portion 113da of one fourth portion. The first portion 113a and the end portion 113da are adjacent to each other, sandwiching a portion that is in communication with the conductive layer 105a. Further, another third portion 113c is provided around the second portion 113b and an end portion 113db of another fourth portion. Other third portion 113c is provided around the end portion 113da and the end portion 113db of the fourth portions. The end portion 113da and the end portion 113db are adjacent to each other, sandwiching a portion that is in communication with the conductive layer 105a. The communication portions 105c are located respectively between the first portion 113a and a third portion 113c, between the second portion 113b and a third portion 113c, between an end portion 113da and a third portion 113c, and between an end portion 113db and a third portion 113c, for example.

The semiconductor memory device 1 may comprise the boundary wall 40 that has a shape of the above-described mask patterns. Such a boundary wall 40 may include a first wall corresponding to the first portion 113, a second wall corresponding to the third portion 113c and a third wall corresponding to the fourth portion 113da or 113db, for example.

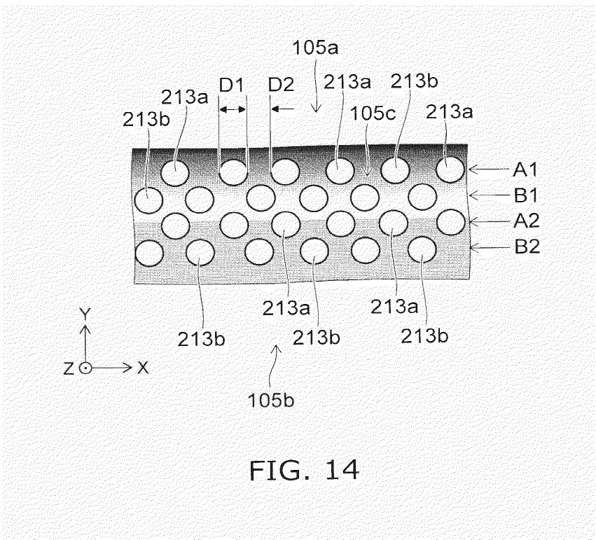

FIG. 14 is a schematic plan view showing a mask pattern according to another variation of the embodiment. A plurality of holes 213 may be provided between the conductive layer 105a and the conductive layer 105b, as shown in FIG. 14. The holes 213 are formed to extend from the upper surface of the conductive layer 105 the insulating layer 31. The holes 231 are in communication with the insulating layer 31.

For example, holes 213 aligned in the X direction may be regard as a group of first holes 213a or a group of second holes 213b. For example, in a row Aₗ on the conductive layer 105a side, holes are regarded as the first holes 213a as shown in FIG. 14. In a row B₁ adjacent to the row A₁, holes are regarded as the second holes 213b. Similarly, holes in a row A₂ are regarded as the first holes 213a, and holes in a row B₂ are regarded as the second holes 213b.

When viewed in the Y direction, the second holes 213b are located between the first holes 213a adjacent to each other in the X direction. Further, the first holes 213a are located between the second holes 213b adjacent to each other in the X direction. For example, each hole 213 have a diameter D₁, and the holes 213 are arranged with a distance D₂ between adjacent holes 213 in the X direction so that D₁>D₂. Thus, the holes 213 each has a part that overlaps with each other in the Y direction. The communication portions 105c may be provided between the adjacent holes 213.

The boundary wall 40 formed by using the conductive layer 105 as an etching mask, for example, has a structure including a plurality of pillars. The plurality of pillars are provided with overlap parts respectively, and may prevent the etchant from penetrating from the memory area MA into the peripheral area PA. For example, the etching period for removing the sacrifice layers 103 may be adjusted to be longer than a period for completely removing the sacrifice layers 103 in the memory area MA and shorter than a period before the etchant penetrates through the communication portion 105c into the peripheral area PA. Thus, it is possible to prevent the etchant from penetrating into the peripheral area PA as shown by shadowing in FIG. 14.

As described above, in the embodiment, the conductive layer 105 is used as an etching mask for forming a boundary wall 40 between the memory area MA and the peripheral area PA around the memory area MA. The conductive layer 105 has the conductive layer 105a on the memory area MA, the conductive layer 105b on the peripheral area PA and the communication portion 43. The communication portion 43 is provided as a part of the boundary between the conductive layers 105a and 105b and provides an electrical connection therebetween. As a result, an opening may be formed in the conductive layer 105, which has flat inner walls and separates the conductive layer 105a and the conductive layer 105b from each other with a smaller distance. Thus, the boundary wall 40 is formed around the memory area MA, which may improve space efficiency.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for forming a pattern in a conductive layer, the method comprising:
forming the conductive layer on an insulating layer;
forming an etching mask on the conductive layer, the etching mask including:
a first portion masking a first area of the conductive layer,
a second portion masking a second area that surrounds the first area via at least one opening that defines a boundary between the first portion and the second portion, the at least one opening includes overlapping portions, and
a first communication portion connecting the first portion and the second portion, the first communication portion being provided between the overlapping portions; and
selectively etching the conductive layer to reach the insulating layer by using the etching mask.

2. The method according to claim 1, wherein
the etching mask includes a first opening and a second opening separated from the first opening, and
the first communication portion is provided between overlapping portions of the first opening and the second opening.

3. The method according to claim 2, wherein
the etching mask includes a third opening and a second communication portion provided between overlapping portions of the first opening or the second opening and the third opening.

4. The method according to claim 1, wherein
the etching mask includes a plurality of openings having parts overlapping with each other in a direction from the first area toward the second area, and
the first communication portion is provided between the parts overlapping with each other.

5. A semiconductor memory device comprising:
a first area including:
a plurality of electrodes stacked in a first direction;
a semiconductor layer extending through the plurality of electrodes in the first direction; and
a memory layer provided between each of the plurality of electrodes and the semiconductor layer;
a second area surrounding the first area;
a boundary wall between the first area and the second area, the boundary wall having overlapping portions that overlap with each other in a second direction from the first area toward the second area; and
a communication portion provided between the overlapping portions of the boundary wall,
the first area being in communication with the second area via the communication portion.

6. The device according to claim 5, wherein
the boundary wall includes a plurality of pillars extending in the first direction.

7. The device according to the claim 6, wherein
the plurality of pillars have overlapping portions that overlap with each other in the second direction.

8. The device according to claim 5, further comprising:
a conductive layer electrically connected to an end of the semiconductor layer; and
an interconnect electrically connected to another end of the semiconductor layer and extending in a second direction,
the plurality of electrodes located between the conductive layer and the interconnect, and
the boundary wall located between the conductive layer and the interconnect.

9. The device according to claim 8, wherein
the boundary wall has a bottom face and a top face, the bottom face being located at a level below a first electrode that is located at a lower end of the plurality of electrodes, and the top face being located at a level above a second electrode that is located at a top end of the plurality of electrodes.

10. The device according to claim 9, wherein
the bottom face of the boundary wall is located in the conductive layer; and
the top face of the boundary wall is located at a level between the interconnect and the second electrode.

11. The device according to claim 5, wherein
the boundary wall includes a first wall and a second wall separated from the first wall, the first wall including two end portions adjacent to each other, and the second wall overlapping with the two end portions in the second direction; and
the first communication portion is provided between one of the two end portions and the second wall.

12. The device according to claim 5, wherein
the boundary wall includes a first wall, a second wall, a third wall and a fourth wall, which are separated from each other;
the first wall has two end portions;
the second wall is provided between the two end portions;
the third wall overlaps with one of the two end portions and the second wall; and
the fourth wall overlaps with the other of the two end portions and the second wall.

13. A method of manufacturing a semiconductor memory device, the method comprising:
forming a stacked body including a first insulating layer and a sacrifice layer stacked on the first insulating layer;
forming a conductive layer on the stacked body;
forming a first groove that separates the conductive layer into a first area and a second area surrounding the first area, the first groove including a first portion and a second portion that overlap with each other in a direction from the first area toward the second area, and providing a communication portion between the first portion and the second portion, the communication portion electrically connecting the first area to the second area;
forming a second groove by etching the stacked body using the conductive layer as a mask, the second groove separating the stacked body into a memory area and a peripheral area surrounding the memory area;
forming a boundary wall in the second groove between the memory area and the peripheral area; and
forming an electrode in the memory area by replacing the sacrifice layer with metal layer.

14. The method according to claim 13, wherein
the sacrifice layer are selectively removed by using an etchant for which the first insulating layer and the second insulating layer have resistivity, and
the etching is performed for a period that is longer than a period enough to remove the sacrifice layer and shorter than a period that causes the etchant to penetrate into the peripheral area through the communication portion.

15. The method according to claim 13, further comprising:
forming a memory hole extending through the stacked body in the stacked direction in the first area;
forming a memory layer on a side wall of the memory hole; and
forming a semiconductor layers on the memory layer.

16. The method according to claim 13, further comprising:
forming a slit extending through the stacked body in the stacked direction in the first are, the slit dividing the stacked body, wherein the sacrifice layer is replaced via the slit with the metal layer.
